(19) United States
(12) Patent Application Publication
(10) Pub. No.: US 2026/0123544 A1
(43) Pub. Date: Apr. 30, 2026

(54) SEMICONDUCTOR PACKAGE

(71) Applicant: Samsung Electronics Co., Ltd., Suwon-si (KR)

(72) Inventors: Haseob SEONG, Suwon-si (KR); Dawoon JUNG, Suwon-si (KR)

(73) Assignee: Samsung Electronics Co., Ltd., Suwon-si (KR)

(21) Appl. No.: 19/303,561

(22) Filed: Aug. 19, 2025

(30) Foreign Application Priority Data
Oct. 25, 2024 (KR) 10-2024-0147932

(51) Int. Cl. H01L 25/16; H01L 23/00; H01L 23/31; H10B 80/00

(52) U.S. Cl. CPC H10W 90/00; H10B 80/00; H10W 74/111; H10W 72/952; H10W 90/792

(57) ABSTRACT

A semiconductor package includes a base chip having a first horizontal width, a plurality of memory chips on the base chip each memory chip of the plurality of memory chips having a second horizontal width, and a sealant sealing a side surface of the base chip, side surfaces of the plurality of memory chips, and a portion of a lower surface of a first memory chip that is lowermost among the plurality of memory chips, the portion of the lower surface of the first memory chip not contacting the base chip, wherein the first horizontal width is less than the second horizontal width.

### CROSS-REFERENCE TO RELATED APPLICATION

This application is based on and claims priority under 35 U.S.C. § 119 to Korean Patent Application No. 10-2024-0147932, filed on Oct. 25, 2024, in the Korean Intellectual Property Office, the disclosure of which is incorporated by reference herein in its entirety.

### BACKGROUND

With the rapid development of the electronics industry and demands of users, electronic devices are becoming increasingly smaller and lighter. As electronic devices become smaller and lighter, semiconductor packages used for the electronic devices are becoming smaller and lighter, and high integration of semiconductor elements is required. In order to achieve miniaturization, light weight, high performance, large capacity, and high reliability, research and development are continuously being conducted on semiconductor chips having a through silicon via (TSV) structure and semiconductor packages having a chip stacking structure in which the semiconductor chips are stacked.

In particular, when constructing a chip stacking structure by stacking a plurality of semiconductor chips, reliability may be reduced due to separation between semiconductor chips and separation between a semiconductor chip and a molding portion.

### SUMMARY

Some example embodiments of inventive concepts provide a semiconductor package with improved reliability by reducing, or preventing, corner separation in a structure in which a plurality of memory chips are stacked.

Also, objects to be achieved by the inventive concepts are not limited to the objects described above, and other objects may be clearly understood by those skilled in the art from the descriptions below.

According to some example embodiments of the inventive concepts, a semiconductor package includes a base chip having a first horizontal width, a plurality of memory chips on the base chip, each memory chip of the plurality of memory chips having a second horizontal width, and a sealant sealing a side surface of the base chip, side surfaces of the plurality of memory chips, and a portion of a lower surface of a first memory chip at a lowermost portion among the plurality of memory chips, the portion of the lower surface of the first memory chip not contacting the base chip, wherein the first horizontal width is less than the second horizontal width.

According to some example embodiments of the inventive concepts, a semiconductor package includes a base chip having a first horizontal width, a plurality of memory chips stacked on the base chip through hybrid copper bonding (HCB) and having a second horizontal width, a redistribution layer on a lower surface of the base chip, and a sealant sealing a side surface of the base chip, side surfaces of the plurality of memory chips, and a portion of a lower surface of a first memory chip at a lowermost portion among the plurality of memory chips, the portion of the lower surface of the first memory chip not contacting the base chip, wherein the first horizontal width is less than the second horizontal width.

According to some example embodiments of the inventive concepts, a semiconductor package includes a package substrate, a first semiconductor device on the package substrate, and at least one second semiconductor device is adjacent to the first semiconductor device on the package substrate, wherein the second semiconductor device has a package structure including a base chip having a first horizontal width, a plurality of memory chips on the base chip, each memory chip of the plurality of memory chips having a second horizontal width, and a sealant sealing a side surface of the base chip, side surfaces of the plurality of memory chips, and a portion of a lower surface of a first memory chip that is lowermost among the plurality of memory chips, wherein the portion of the lower surface of the first memory chip is not in contact with the base chip, and wherein the first horizontal width is less than the second horizontal width.

### BRIEF DESCRIPTION OF THE DRAWINGS

Some example embodiments of the inventive concepts will be more clearly understood from the following detailed description taken in conjunction with the accompanying drawings in which:

FIG. 1A and FIG. 1B are respectively a plan view and a cross-sectional view of a semiconductor package according to some example embodiments;

FIG. 2 is an enlarged view of portion EX of FIG. 1B;

FIG. 3A and FIG. 3B are conceptual views illustrating delamination that may occur in a semiconductor package;

FIG. 4 is a cross-sectional view of a semiconductor package according to some example embodiments;

FIG. 5 is a cross-sectional view of a semiconductor package according to some example embodiments;

FIG. 6 is a cross-sectional view of a semiconductor package according to some example embodiments;

FIG. 7 is a cross-sectional view of a semiconductor package according to some example embodiments;

FIG. 8 is a cross-sectional view of a semiconductor package according to some example embodiments;

FIG. 9A and FIG. 9B are respectively a perspective view and a cross-sectional view of a system package according to some example embodiments;

FIG. 10 to FIG. 13 are plan views briefly illustrating a method of manufacturing a semiconductor package according to some example embodiments; and

FIG. 14 to FIG. 20 are cross-sectional views briefly illustrating a method of manufacturing a semiconductor package according to some example embodiments.

### DETAILED DESCRIPTION OF THE EMBODIMENTS

Hereinafter, some example embodiments of the inventive concepts are described in detail with reference to the attached drawings. The same reference numerals are used for the same components in the drawings, and redundant descriptions thereof are omitted.

When an element is referred to as being “connected to” or “electrically connected to” another element, the element may be directly connected to the other element, or one or more other intervening elements may be present. For example, an element described as being “connected to” another element may be “electrically connected to” the other element. In contrast, when an element is referred to as being “directly connected to” another element there are no intervening elements present.

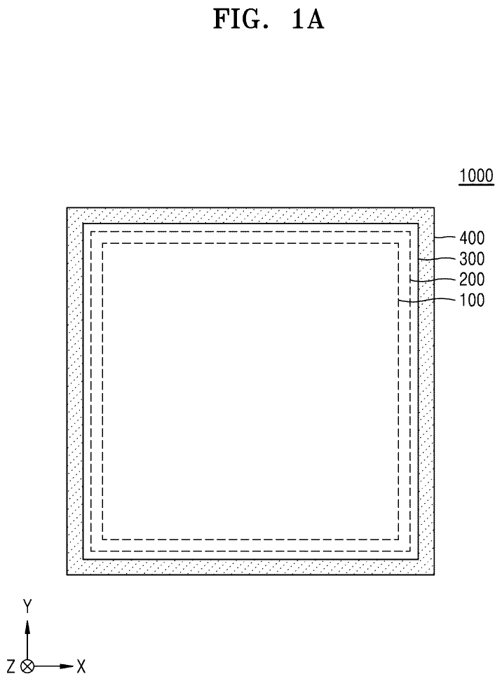

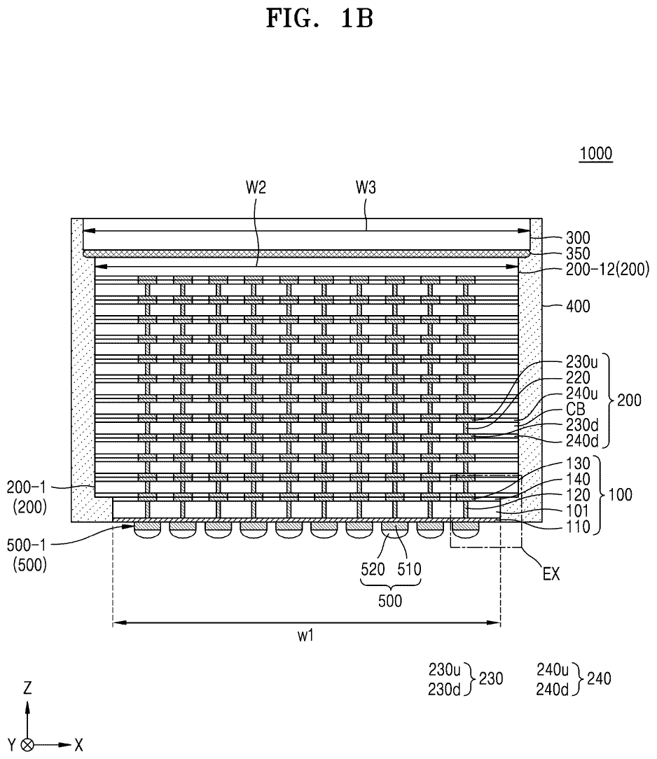

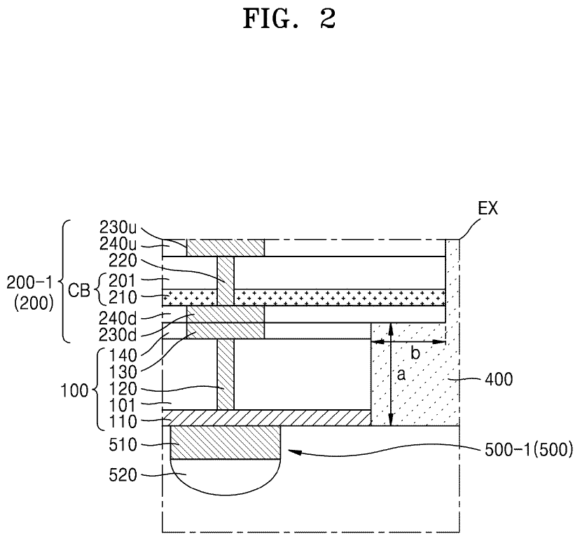

FIGS. 1A and 1B are respectively a plan view and a cross-sectional view of a semiconductor package 1000 according to some example embodiments. FIG. 2 is an enlarged view of a portion EX of FIG. 1B.

Referring to FIG. 1A to FIG. 2, the semiconductor package 1000 according to some example embodiments may include a base chip 100, a plurality of memory chips 200, a top dummy chip 300, a sealant 400, and/or external connection terminals 500.

The base chip 100 may include a substrate body 101, an active layer 110, through-electrodes 120, upper pads 130, and/or a protective layer 140. The base chip 100 according to some example embodiments may have a smaller size than the memory chips 200 provided on the upper side, as illustrated in FIG. 1B.

In the drawings, an X-axis direction and a Y-axis direction indicate directions parallel to an upper or lower surface of the base chip 100 and may be directions perpendicular to each other. A Z-axis direction may indicate a direction perpendicular to the upper or lower surface of the base chip 100. Also, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The substrate body 101 may include, for example, a semiconductor element, such as silicon (Si) and/or germanium (Ge). The substrate body 101 may also include a compound semiconductor, such as silicon carbide (SiC), gallium arsenide (GaAs), indium arsenide (InAs), and/or indium phosphide (InP). The substrate body 101 may have a silicon on insulator (SOI) structure. For example, the substrate body 101 may include a buried oxide layer (BOX). The substrate body 101 may include a structure, such as a conductive region, for example, a well doped with an impurity, and/or source/drain regions doped with impurities. The substrate body 101 may include various device isolation structures, such as a shallow trench isolation (STI) structure.

The active layer 110 may include an integrated circuit layer and multiple wiring layers on the integrated circuit layer. The integrated circuit layer may include various types of devices. For example, an integrated circuit layer may include various active and/or passive components, for example, field effect transistors (FETs) such as planar FETs or FinFETs, flash memory, a memory device such as dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), and/or resistive random access memory (RRAM), logic devices such as an AND gate, an OR gate, and/or an NOT gate, system large scale integration (LSIs), complementary metal oxide semiconductor (CMOS) imaging sensors (CIS's), a micro-electro-mechanical system (MEMS), and so on.

A multi-wiring layer may connect at least two components to each other, connect components to conductive regions of the substrate body 101, and/or connect components to the external connection terminals 500. Also, the multi-wiring layer may connect the through-electrodes 120 to the external connection terminals 500. The multi-wiring layer may include, for example, wiring lines and/or contacts and/or vias. In the semiconductor package 1000 of some example embodiments, the active layer 110 may be provided below the through-electrodes 120. However, in some example embodiments, the active layer 110 may also be provided above the through-electrodes 120. For example, a positional relationship between the active layer 110 and the through-electrodes 120 may be relative.

In the semiconductor package 1000 of some example embodiments, the integrated circuit layer of the active layer 110 in the base chip 100 may include a plurality of logic elements. The base chip 100 may be provided below the memory chips 200. The base chip 100 may integrate signals from the memory chips 200 and transmit the integrated signals to the outside, and also transmits the integrated signals and power from the outside to the memory chips 200. Accordingly, the base chip 100 may be referred to as a buffer chip and/or an interface chip.

In some example embodiments, the base chip 100 may include a controller that controls signal transmission between the memory chips 200 and an external device. When the base chip 100 includes a controller, the base chip 100 may be referred to as a logic chip, a control chip, or so on. In some example embodiments, the base chip 100 may include a power management integrated circuit (PMIC) that manages power and/or a clock signal. For reference, when the base chip 100 is referred to as a buffer chip or so on, the memory chips 200 may be referred to as core chips. The base chip 100 is not limited to a buffer chip or a logic chip, and for example, the base chip 100 may include a memory chip.

The through-electrodes 120 may pass through the substrate body 101 to extend from an upper surface of the substrate body 101 to the lower surface of the substrate body 101. In some example embodiments, the through-electrodes 120 may each, or one or more, extend into the active layer 110. In the semiconductor package 1000 of some example embodiments, the substrate body 101 may include silicon (Si), and thus, the through-electrodes 120 may each, or one or more, be referred to as a through silicon via (TSV).

The through-electrodes 120 may each, or one or more, have a pillar shape and include a barrier layer on an outer surface and/or a buried conductive layer on the inside. The barrier layer may include at least one material selected from among Ti, TiN, Ta, TaN, Ru, Co, Mn, WN, Ni, and/or NiB. The buried conductive layer may include at least one material selected from among a Cu alloy, such as CuSn, CuMg, CuNi, CuZn, CuPd, CuAu, CuRe, or CuW, W, a W alloy, Ni, Ru, and/or Co. In addition, an insulating layer may be between the through-electrodes 120 and the substrate body 101, and/or between the through-electrodes 120 and the active layer 110. The insulating layer may include, for example, an oxide film, a nitride film, a carbide film, a polymer, or a combination thereof.

The upper pads 130 may be provided on an upper surface of the substrate body 101 and may be respectively connected to the through-electrodes 120. The upper pads 130 may each, or one or more, include, for example, at least one of aluminum (Al), copper (Cu), nickel (Ni), tungsten (W), platinum (Pt), and/or gold (Au). In the semiconductor package 1000 of some example embodiments, the upper pads 130 may each include copper (Cu). However, a material of each of the upper pads 130 is not limited to copper (Cu).

The protective layer 140 may be provided on the upper surface of the substrate body 101. The protective layer 140 may include, for example, an oxide film, a nitride film, a carbide film, a polymer, and/or a combination thereof. In some example embodiments, the protective layer 140 may have a multi-layer structure. For example, the protective layer 140 may include a first insulating layer including a silicon oxide film, a second insulating layer including a silicon nitride film, and/or a third insulating layer including a silicon oxide film.

The upper pads 130 may each, or one or more, pass through at least part of the protective layer 140. For example, the upper pads 130 may completely, (or substantially), pass through the protective layer 140 or may each, or one or more, pass through a part of the protective layer 140, and may be buried in the protective layer 140. The upper pads 130 may be respectively connected to the through-electrodes 120 on an upper surface of the substrate body 101 or inside the protective layer 140. Although not illustrated, a lower protective layer may be provided on a lower surface of the active layer 110.

The base chip 100 may have a first horizontal width w1 in a horizontal direction (the X-axis direction and/or the Y-axis direction). A horizontal width relationship between the base chip 100 and the memory chips 200 is described below.

The memory chips 200 may be stacked on the base chip 100. In the semiconductor package 1000 of some example embodiments, 12 memory chips 200, for example, a first memory chip to a 12th memory chip 200-1 to 200-12, may be stacked on the base chip 100. The number of memory chips 200 stacked on the base chip 100 is not limited to 12. For example, 2 to 11 memory chips 200 or 13 or more memory chips 200 may be stacked on the base chip 100.

For example, the number of the memory chips 200 in the semiconductor package 1000 of some example embodiments may be 4n (n is a natural number). Accordingly, the semiconductor package 1000 may include the memory chips 200 in multiples of 4, such as 4, 8, or 12. Four memory chips 200 may have the same stack identification (ID) to be tested and operated together. For example, when the semiconductor package 1000 includes 12 memory chips 200, the first memory chip to a fourth memory chip 200-1 to 200-4 may have a first stack ID, a fifth memory chip to an eighth memory chip 200-5 to 200-8 may have a second stack ID, and a ninth memory chip to the 12th memory chip 200-9 to 200-12 may have a third stack ID. However, the semiconductor package 1000 of some example embodiments is not limited to the memory chips 200 in multiples of 4 and stack IDs corresponding thereto. For example, the semiconductor package 1000 of some example embodiments may include memory chips 200 in multiples of 2 and stack IDs corresponding thereto, or may include memory chips 200 in multiples of 8 and stack IDs corresponding thereto.

The memory chips 200 may all, or one or more, have the same size and structure. However, as illustrated in FIG. 1B, the memory chip provided at an uppermost portion of the memory chips 200, for example, the 12th memory chip 200-12 may not include a through-electrode. The 12th memory chip 200-12 may be thicker in a vertical direction (the Z-axis direction) than the other memory chips 200. Hereinafter, the first memory chip 200-1 is described for the sake of convenience of description.

The first memory chip 200-1 may include a chip body layer CB, the through-electrode 220, a connection pad 230, and/or a protective layer 240. The chip body layer CB may include a substrate body 201 and/or an active layer 210, as illustrated in FIG. 2. The substrate body 201 may be the same as the substrate body 101 of the base chip 100.

The active layer 210 may include a plurality of memory elements. For example, the active layer 210 may include volatile memory devices, such as DRAM and/or SRAM, and/or nonvolatile memory devices, such as PRAM, MRAM, FeRAM, and/or RRAM. For example, the first memory chip 200-1 in the semiconductor package 1000 of some example embodiments may include DRAM in the active layer 210. Accordingly, the first memory chip 200-1 may be a DRAM chip. For example, the first memory chip 200-1 may be a DRAM chip for high bandwidth memory (HBM). Accordingly, the semiconductor package 1000 of some example embodiments may be an HBM package. However, the semiconductor package 1000 of some example embodiments is not limited to the HBM package.

The through-electrode 220 may pass through the substrate body 201 and/or may extend into the active layer 210 by passing through the substrate body 201. For example, when the first memory chip 200-1 is divided into a cell region and a pad region, and when the through-electrode 220 is formed only in the pad region, the through-electrode 220 may extend into the active layer 210 through the substrate body 201. The other descriptions of the through-electrode 220 are the same as the descriptions of the through-electrodes 120 of the base chip 100.

The connection pad 230 may include a lower pad 230d on a lower surface of the chip body layer CB and/or an upper pad 230u on an upper surface of the chip body layer CB. In a general semiconductor chip, a chip pad may be provided on a lower surface of an active layer. Therefore, the lower pad 230d may correspond to a chip pad of the first memory chip 200-1.

The lower pad 230d may be connected to wires of a multi-wiring layer of the active layer 210 on a lower surface of the chip body layer CB. Also, the lower pad 230d may be connected to the through-electrode 220 through the wires of the multi-wiring layer. Although FIG. 1B illustrates that the lower pad 230d is directly connected to the through-electrode 220, this is for the sake of convenience of illustration, and in reality, the multi-wiring layer of the active layer 210 may be between the through-electrode 220 and the lower pad 230d.

The upper pad 230u may be connected to the through-electrode 220 on an upper surface of the chip body layer CB. Materials of the lower pad 230d and/or the upper pad 230u may be the same as the materials of the upper pads 130 of the base chip 100.

The protective layer 240 may include a lower protective layer 240d on the lower surface of the chip body layer CB and/or an upper protective layer 240u on the upper surface of the chip body layer CB. The protective layer 240 may include, for example, an oxide film, a nitride film, a carbon film, a polymer, and/or a combination thereof. The upper protective layer 240u may be the same as the protective layer 140 of the base chip 100.

In some example embodiments, the lower protective layer 240d may have a multi-layer structure. For example, the lower protective layer 240d may include a first insulating layer including a tetra-ethyl ortho-silicate (TEOS) oxide film, a second insulating layer including a silicon nitride film, and/or a third insulating layer including a TEOS oxide film.

The upper pad 230u may pass through at least part of the upper protective layer 240u. For example, the upper pad 230u may completely, (or substantially), pass through the upper protective layer 240u, and/or may pass through a part of an upper portion of the upper protective layer 240u to be buried in the upper protective layer 240u. The upper pad 230u may be connected to the through-electrode 220 on the upper surface of the chip body layer CB and/or inside the upper protective layer 240u.

The lower pad 230d may pass through at least part of the lower protective layer 240d. For example, a thick pad metal layer may be within the lower protective layer 240d, and the lower pad 230d may be connected to the pad metal layer by passing through a part of the lower protective layer 240d. For example, the pad metal layer may be connected to wires of a multi-wiring layer of the active layer 210. The pad metal layer may include, for example, aluminum (Al). Therefore, the lower pad 230d may be connected to the wires of the multi-wiring layer through the pad metal layer, and may also be connected to the through-electrode 220 through the wires of the multi-wiring layer.

The memory chips 200 according to some example embodiments may have a greater size than the base chip 100. For example, the memory chips 200 may each, or one or more, have a second horizontal width w2 in a horizontal direction (the X-axis direction and/or Y-axis direction), and the second horizontal width w2 may be greater than the first horizontal width w1 of the base chip 100. Thicknesses of the memory chips 200 in the vertical direction (the Z-axis direction), for example, a thickness of the first memory chip 200-1, may be less than or equal to a thickness of the base chip 100.

As illustrated in FIG. 2, a horizontal width b of the first memory chip 200-1 extending outside the base chip 100 and a height a of the base chip 100 may form an aspect ratio a/b. Here, the horizontal width b may correspond to half of a difference between the first horizontal width w1 of the base chip 100 and the second horizontal width w2 of each of the memory chips 200. That is, b=(w2−w1)/2. The aspect ratio a/b may be a ratio, for example an optimal ratio, for reducing, or preventing, separation between the memory chips 200, for example, the first memory chip 200-1 and the base chip 100. According to some example embodiments, the aspect ratio a/b may be 20 or less. For example, when the height a of the base chip 100 is 60 μm, the first horizontal width w1 of the base chip 100 is 90 μm, and the second horizontal width w2 of the first memory chip 200-1 is 100 μm, the aspect ratio a/b may be 12.

In the semiconductor package 1000 of some example embodiments, the memory chips 200 may be stacked on the base chip 100 or the memory chip 200 immediately below through hybrid copper bonding (HCB). Here, HCB may mean a bonding that is a combination of pad-to-pad bonding and insulator-to-insulator bonding. In addition, a pad is usually formed of copper (Cu), and accordingly, the pad-to-pad bonding is also called Cu-to-Cu bonding.

For example, the upper pads 130 of the base chip 100 may be bonded to the lower pad 230d of the first memory chip 200-1, and the protective layer 140 of the base chip 100 may be bonded to the lower protective layer 240d of the first memory chip 200-1, and accordingly, HCB may be formed between the base chip 100 and the first memory chip 200-1. Accordingly, connection terminals may not be provided between the base chip 100 and the first memory chip 200-1. In the memory chips 200, between two adjacent memory chips, the upper pad 230u and the upper protection layer 240u on an upper surface of the memory chip 200 in a lower portion may be respectively bonded to the lower pad 230d and the lower protection layer 240d on a lower surface of the upper memory chip 200 to form an HCB. Therefore, connection terminals may not be provided between the memory chips 200.

However, the bonding between the memory chip 200 and the base chip 100 and the bonding between the memory chips 200 are not limited thereto, and the memory chips 200 may be stacked on the base chip 100 and/or the memory chip 200 immediately below through thermal compression bonding (TCB).

The top dummy chip 300 may be stacked on an upper portion of the memory chips 200. The top dummy chip 300 may be provided on the upper portion of the memory chips 200 to meet a height specification of the semiconductor package 1000. For example, a height, an area, and so on may be determined by a solid state technology association (JEDEC) specification for an HBM package. When the semiconductor package 1000 is an HBM package, the top dummy chip 300 having an appropriate height may be provided on the memory chips 200 to meet a JEDEC height specification. In some example embodiments, the top dummy chip 300 may also be omitted.

The top dummy chip 300 may have a greater size than the base chip 100 and/or the memory chips 200. For example, the top dummy chip 300 may have a third horizontal width w3 along the horizontal direction (the X-axis direction and/or Y-axis direction), and the third horizontal width w3 may be greater than or equal to the second horizontal width w2 of each of the memory chips 200. A thickness in the vertical direction (the Z-axis direction) of the top dummy chip 300 may be greater than a thickness of the base chip 100. For example, the thickness of the top dummy chip 300 may be greater than the thickness of the base chip 100 to meet the JEDEC height specification.

The top dummy chip 300 may be stacked on an upper portion of the memory chips 200 through an adhesive layer 350. For example, the top dummy chip 300 may be stacked on the 12th memory chip 200-12, and the adhesive layer 350 may be between the top dummy chip 300 and the 12th memory chip 200-12. In some example embodiments, the adhesive layer 350 may include a non-conductive film (NCF) and/or a die attach film (DAF). However, an attachment method between the top dummy chip 300 and the memory chips 200 is not limited thereto, and the top dummy chip 300 may be bonded to the memory chips 200 through HCB without the adhesive layer 350.

In the semiconductor package 1000 according to some example embodiments, the adhesive layer 350 may not extend to a side surface of the top dummy chip 300. For example, when the adhesive layer 350 which is an NCF is provided between the top dummy chip 300 and the 12th memory chip 200-12 and bonding is performed through a thermal compression process, the adhesive layer 350 may have a fillet extending to both sides. When the fillet covers a side surface of the top dummy chip 300 and/or covers an upper surface of the top dummy chip 300, the packaging quality of the semiconductor package 1000 may be degraded. In the semiconductor package 1000 according to some example embodiments, the third horizontal width w3 of the top dummy chip 300 is formed to be greater than or equal to the second horizontal width w2 of each, or one or more, of the memory chips 200, and accordingly, the adhesive layer 350 may not extend to the side surface of the top dummy chip 300. Accordingly, it is possible to reduce, or prevent, the quality of the semiconductor package 1000 from being degraded due to the adhesive layer 350 and the reliability of the semiconductor package 1000 may be improved.

The sealant 400 may seal a side surface of the base chip 100, side surfaces of the memory chips 200, a portion of a lower surface of the first memory chip 200-1 which is not in contact with the base chip 100, and/or a side surface of the top dummy chip 300. As illustrated in FIG. 1B, the sealant 400 may not cover an upper surface of the top dummy chip 300. Accordingly, the upper surface of the top dummy chip 300 may be exposed from the sealant 400. However, in some example embodiments, the sealant 400 may also cover the upper surface of the top dummy chip 300. Also, the sealant 400 may not cover a lower surface of the base chip 100. Accordingly, the sealant 400 may not cover the external connection terminals 500 on the lower surface of the base chip 100.

In some example embodiments, the sealant 400 may include epoxy mold compound (EMC). However, a material of the sealant 400 is not limited to the EMC. For example, the sealant 400 may be formed of a photosensitive material, such as photo-imageable encapsulant (PIE). A part of the sealant 400 may include an insulating material, such as a silicon oxide film, a silicon nitride film, and/or a silicon oxynitride film. However, the sealant 400 is not limited thereto and may also be formed of a thermosetting resin such as an epoxy resin, a thermoplastic resin such as a polyimide, and/or a resin including a reinforcing material such as an inorganic filler, specifically, Ajinomoto build-up film (ABF), FR-4, BT, or so on.

The external connection terminals 500 may be provided on a lower surface of the base chip 100. The external connection terminals 500 may be respectively connected to wires of the multi-wiring layer of the active layer 110. The external connection terminals 500 may be respectively connected to the through-electrodes 120 through the wires of the multi-wiring layer. Although not illustrated in the drawings, chip pads may be provided on a lower surface of the base chip 100, and the external connection terminals 500 may be respectively provided on the chip pads.

The external connection terminals 500 may each, or one or more, include a pillar 510 and/or a bump 520. The pillar 510 may have a cylindrical shape and include, for example, nickel (Ni), copper (Cu), palladium (Pd), platinum (Pt), gold (Au), and/or a combination thereof. In some example embodiments, the pillar 510 may serve as a chip pad of the base chip 100 and may include copper (Cu). Accordingly, the pillar 510 may be referred to as a bump pad, a Cu-pad, a Cu-pillar, or so on. In addition, when the pillar 510 serves as a chip pad, a separate chip pad may not be formed on the lower surface of the base chip 100.

The bump 520 may be provided on the pillar 510 and have a hemispherical shape. The bump 520 may include, for example, solder. The solder may include tin (Sn), indium (In), bismuth (Bi), antimony (Sb), copper (Cu), silver (Ag), zinc (Zn), and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or so on. In some example embodiments, the bump 520 may be referred to as solder, a solder bump, or so on. In addition, an intermediate layer may be formed at a contact interface between the pillar 510 and the bump 520. The intermediate layer may include an intermetallic compound (IMC) formed by a reaction of metal materials included in the pillar 510 and the bump 520 at a relatively high temperature.

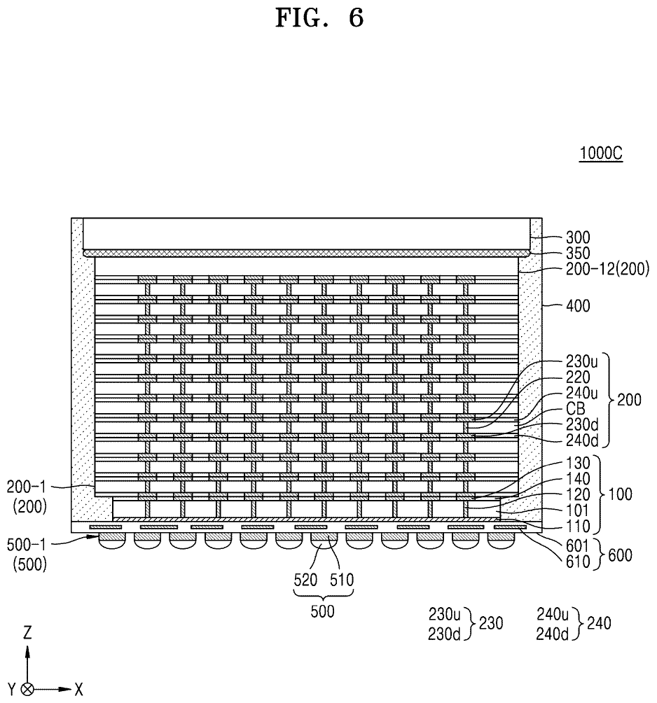

In some example embodiments, the external connection terminals (500) may be provided within a region vertically overlapping the base chip 100. For example, a first external connection terminal 500-1 at an outermost end among the external connection terminals 500 may be provided on a lower surface of the base chip 100. However, the arrangement of the external connection terminals 500 is not limited thereto, and the first external connection terminal 500-1 may be provided across the lower surface of the base chip 100 and the sealant 400 and/or may be provided to be in contact with only a lower surface of the sealant 400. In this regard, descriptions are made below with reference to FIG. 6 to FIG. 8.

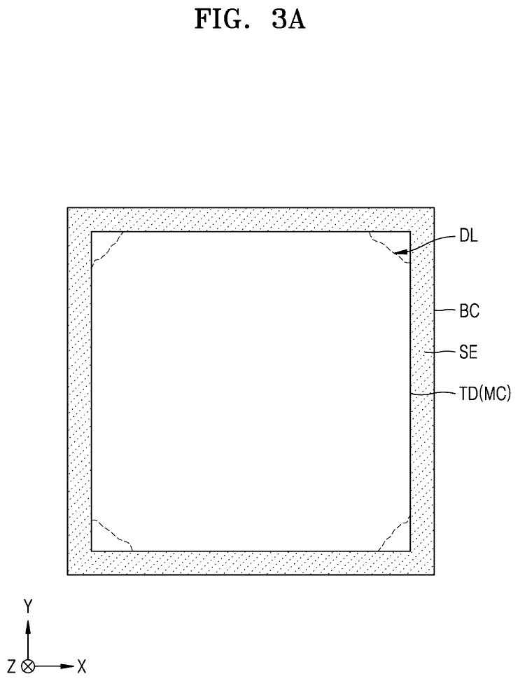

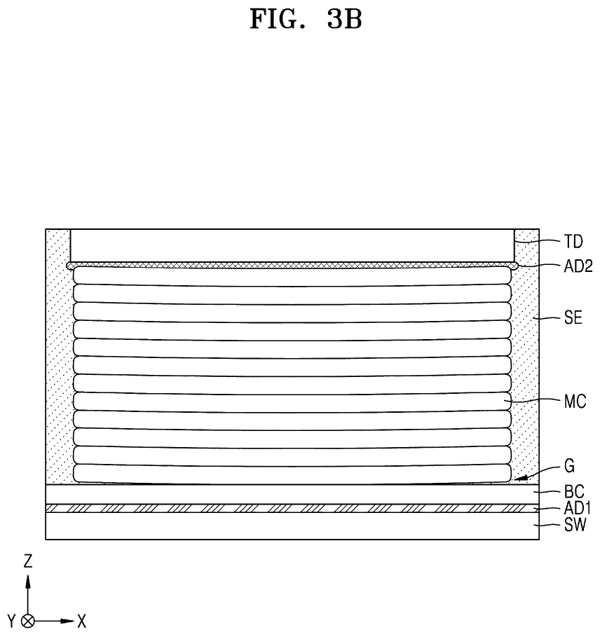

FIGS. 3A and 3B are conceptual views illustrating a separation phenomenon that may occur in a semiconductor package.

Referring to FIGS. 3A and 3B, a plurality of memory chips MC may be stacked on a base chip BC. For example, in a process of stacking the memory chips MC on the base chip BC, the base chip BC may be in a wafer state. The base chip BC in a wafer state may be bonded and fixed onto a support wafer SW through an adhesive layer AD. FIG. 3B illustrates only a portion corresponding to one base chip BC for the sake of convenience.

In a process of stacking the memory chips MC on the base chip BC, HCB may be performed for each, or one or more, of the memory chips MC. Warpage may occur in the base chip BC and the memory chips MC. For example, a separation phenomenon may occur in which a gap (G) is formed at a corner and/or edge of the memory chips MC, particularly, the lowest memory chip MC. Here, the corner may refer to a top portion of a lower surface of the memory chip MC, and the edge may refer to a side portion of the lower surface of the memory chip MC. FIG. 3A illustrates a delamination DL occurring at the corner of the lowest memory chip MC as an example. The gap G due to the delamination phenomenon may progress to a sealant SE surrounding the memory chips MC in the next process, underfill, or so on to cause cracks in the sealant SE, the underfill, or so on, and may reduce the reliability of the semiconductor package and the reliability of a system package or product including the semiconductor package.

In the semiconductor package 1000 of some example embodiments described with reference to FIG. 1A to FIG. 2, the second horizontal width w2 of each, or one or more, of the memory chips 200 is greater than the first horizontal width w1 of the base chip 100, and accordingly, edges of the memory chips 200 are stacked to be placed on an outer portion of the base chip 100. Accordingly, the corner and/or edge of the first memory chip 200-1, which is a portion where separation may easily occur, may not be in contact with the base chip 100. Because the sealant 400 is filled in a portion of a lower surface of the first memory chip 200-1 which is not in contact with the base chip 100, the separation phenomenon at the corners and/or edges of the memory chips 200, particularly at the corner and/or edge of the first memory chip 200-1, may be effectively reduced, or prevented.

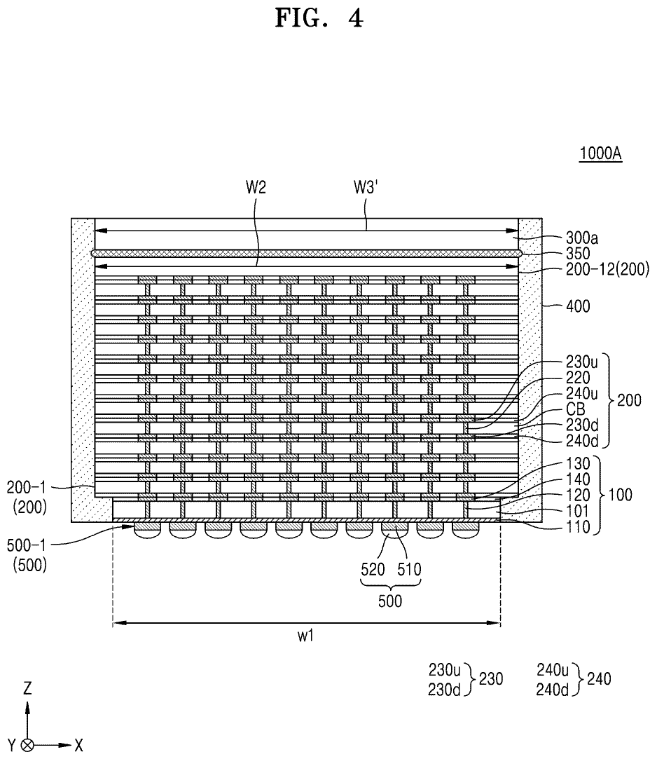

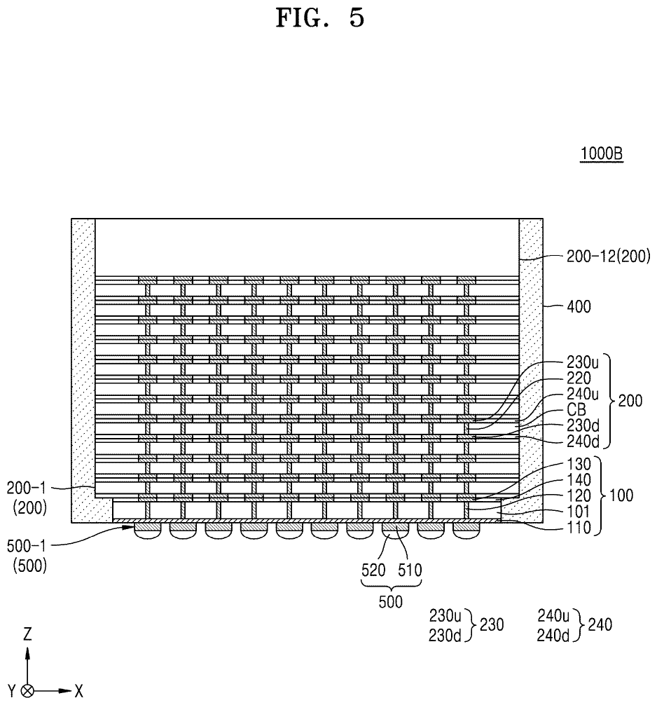

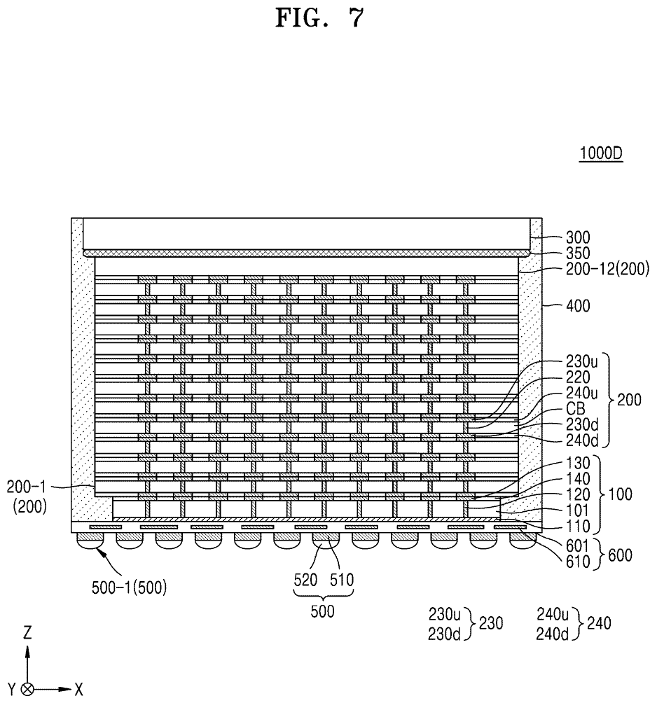

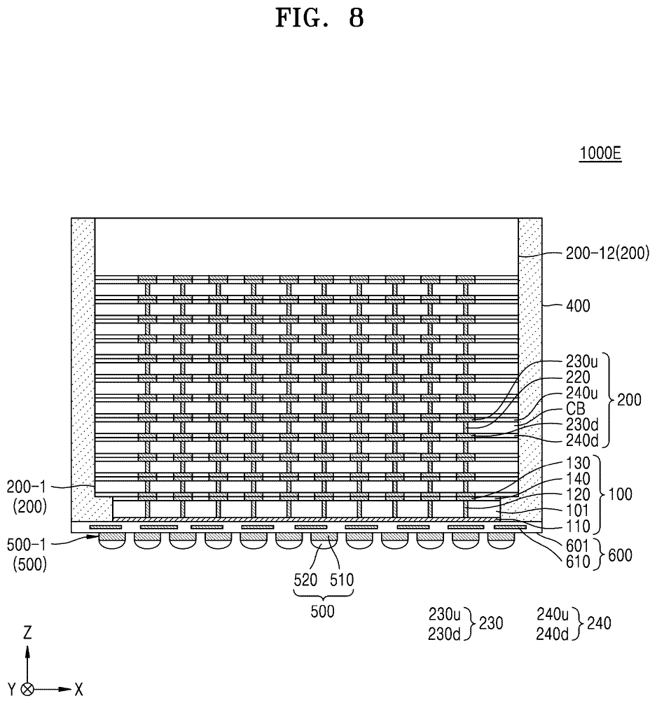

FIG. 4 is a cross-sectional view of a semiconductor package 1000A according to some example embodiments. FIG. 5 is a cross-sectional view of a semiconductor package 1000B according to some example embodiments. FIG. 6 is a cross-sectional view of a semiconductor package 1000C according to some example embodiments. FIG. 7 is a cross-sectional view of a semiconductor package 1000D according to some example embodiments. FIG. 8 is a cross-sectional view of a semiconductor package 1000E according to some example embodiments.

Most of the components of the semiconductor packages 1000A, 1000B, 1000C, 1000D, and 1000E described below and materials forming the components are the same as or similar to the components and materials described above with reference to FIG. 1A to FIG. 2. Therefore, for the sake of convenience of description, a difference from the semiconductor package 1000 of FIG. 1B is described.

Referring to FIG. 4, the semiconductor package 1000A according to some example embodiments may include a base chip 100, a plurality of memory chips 200, a top dummy chip 300a, a sealant 400, and/or external connection terminals 500.

The base chip 100 may have a first horizontal width w1 in a horizontal direction (the X-axis direction and/or Y-axis direction).

The plurality of memory chips 200 may be stacked on the base chip 100. The plurality of memory chips 200 may have greater sizes than a size of the base chip 100. For example, the plurality of memory chips 200 may each, or one or more, have a second horizontal width w2 in the horizontal direction (the X-axis direction and/or Y-axis direction), and the second horizontal width w2 may be greater than the first horizontal width w1 of the base chip 100. Thicknesses in the vertical direction (the Z-axis direction) of the plurality of memory chips 200, for example, a thickness of a first memory chip 200-1, may be less than or equal to a thickness of the base chip 100.

The top dummy chip 300a may be stacked on an upper portion of the plurality of memory chips 200. The top dummy chip 300a may be stacked on the upper portion of the plurality of memory chips 200 through an adhesive layer 350. The top dummy chip 300a may be completely (or substantially) overlapped vertically with the plurality of memory chips 200. For example, the top dummy chip 300a may have a third horizontal width w3′ in the horizontal direction (the X-axis direction and/or Y-axis direction), and the third horizontal width w3′ may be substantially equal to the second horizontal width w2 of each, or one or more, of the plurality of memory chips 200. A thickness in the vertical direction (the Z-axis direction) of the top dummy chip 300a may be greater than the thickness of the base chip 100 and the thicknesses of the plurality of memory chips 200.

The sealant 400 may seal a side surface of the base chip 100, side surfaces of the plurality of memory chips 200, a portion of a lower surface of the first memory chip 200-1 which is not in contact with the base chip 100, and/or a side surface of the top dummy chip 300a. As illustrated in FIG. 4, the sealant 400 may not cover an upper surface of the top dummy chip 300. Accordingly, the upper surface of the top dummy chip 300a may be exposed from the sealant 400. Also, the sealant 400 may not cover a lower surface of the base chip 100. Accordingly, the sealant 400 may not cover the external connection terminals 500 provided on the lower surface of the base chip 100.

Referring to FIG. 5, the semiconductor package 1000B according to some example embodiments may include a base chip 100, a plurality of memory chips 200, a sealant 400, and/or external connection terminals 500.

The semiconductor package 1000B according to some example embodiments may not include a top dummy chip. In this case, a memory chip at an uppermost portion of the plurality of memory chips 200, for example, a 12th memory chip 200-12 may replace the top dummy chip. Compared to the 12th memory chip 200-12 of the semiconductor package 1000 of FIG. 1B, a thickness in the vertical direction (the Z-axis direction) of the 12th memory chip 200-12 of the semiconductor package 1000B in FIG. 5 may be increased to meet a JEDEC height specification. Chips comprising the semiconductor package 1000B, for example, the base chip 100, the first memory chip 200-1, and/or the plurality of memory chips 200 may all, or one or more, be bonded to each other through HCB.

Referring to FIG. 6, the semiconductor package 1000C according to some example embodiments may include a base chip 100, a plurality of memory chips 200, a top dummy chip 300, a sealant 400, external connection terminals 500, and/or a redistribution layer 600.

The redistribution layer 600 may be on a lower side of the base chip 100. The redistribution layer 600 may serve to redistribute a chip pad provided on a lower surface of the base chip 100 to an external region of the base chip 100. The redistribution layer 600 may include a body insulation layer 601 and/or a redistribution line 610.

The body insulation layer 601 may include an insulating material, for example, a photo imageable dielectric (PID) and/or photo imageable polyimide (PID) resin and may further include an inorganic filler. However, a material of the body insulation layer 601 is not limited to the material described above. For example, the body insulation layer 601 may include polymide isoindro quirazorindione (PIQ), polyimide (PI), polybenzoxazole (PBO), and/or so on.

The body insulation layer 601 may have a multi-layer structure according to a multi-layer structure of the redistribution line 610. However, FIG. 6 illustrates the body insulation layer 601 having a single layer structure for the sake of convenience of description. When the body insulation layer 601 has a multi-layer structure, all, or one or more, layers of the body insulation layer 601 may include the same material, or at least one layer may include a different material.

The redistribution line 610 may include multiple layers formed within the body insulation layer 601. The multiple layers of the redistribution line 610 which are arranged in different layers may be connected to each other by vertical vias. Referring to FIG. 6, the vertical vias are not illustrated. The redistribution line 610 and the vertical vias may include, for example, copper (Cu). However, materials of the redistribution line 610 and the vertical vias are not limited to copper (Cu).

The external connection terminals 500 may be provided on a lower portion of the redistribution layer 600. Although not illustrated in FIG. 6, the external connection terminals 500 may be respectively provided on external connection pads on a lower surface of the body insulation layer 601. The external connection pads may be included as a part of the redistribution line 610. However, in some example embodiments, the external connection pads may be treated as separate components from the redistribution line 610.

The external connection terminals 500 may be provided on a lower surface of the redistribution layer 600. The external connection terminals 500 may be electrically connected to the redistribution line 610 through the external connection pads on the lower surface of the redistribution layer 600. The external connection terminals 500 may connect the semiconductor package 1000C to a package substrate of an external system, a main board of an electronic device, such as a mobile device, and/or so on.

In some example embodiments, some of the external connection terminals 500 may be provided on an external region of the base chip 100. For example, some of the external connection terminals 500 may be overlapped with the sealant 400. For example, a first external connection terminal 500-1 provided at an outermost end among the external connection terminals 500 may be provided across the base chip 100 and the sealant 400. The first external connection terminal 500-1 may be provided on a lower surface of the redistribution layer 600 such that a part of the first external connection terminal 500-1 vertically overlaps the base chip 100 and the other portions thereof vertically overlap the sealant 400.

Referring to FIG. 7, the semiconductor package 1000D according to some example embodiments may include a base chip 100, a plurality of memory chips 200, a top dummy chip 300, a sealant 400, external connection terminals 500, and/or a redistribution layer 600.

The redistribution layer 600 may be provided under the base chip 100, and the external connection terminals 500 may be provided under the redistribution layer 600.

The external connection terminals 500 may be electrically connected to the redistribution line 610 through external connection pads provided on a lower surface of the redistribution layer 600. The external connection terminals 500 may connect the semiconductor package 1000D to a package substrate of an external system, a main board of an electronic device such as a mobile device, and/or so on.

A first external connection terminal 500-1 provided at an outermost end among the external connection terminals 500 may be provided so as not to vertically overlap the base chip 100. The first external connection terminals 500-1 may be in contact with the sealant 400 with the redistribution layer 600 therebetween. The first external connection terminal 500-1 may vertically overlap the plurality of memory chips 200. However, the inventive concepts are not limited thereto, and the first external connection terminal 500-1 may be provided an outer side of the redistribution layer 600 so as not to vertically overlap the memory chips 200.

Referring to FIG. 8, a semiconductor package 1000E according to some example embodiments may include a base chip 100, a plurality of memory chips 200, a sealant 400, external connection terminals 500, and/or a redistribution layer 600.

In the semiconductor package 1000B according to some example embodiments, a 12th memory chip 200-12 provided at an uppermost portion of the plurality of memory chips 200 may replace a top dummy chip. The 12th memory chip 200-12 may have a sufficient thickness to meet the JEDEC height specification.

The redistribution layer 600 may be provided at a lower portion of the base chip 100, and the external connection terminals 500 may be provided on a lower portion of the redistribution layer 600. Some of the external connection terminals 500 may be provided in an external region of the base chip 100. Although FIG. 8 illustrates that a first external connection terminal 500-1 is provided across the base chip 100 and the sealant 400, some example embodiments are not limited thereto, and the first external connection terminal 500-1 may be provided so as not to vertically overlap the base chip 100.

A package structure in which the external connection terminals 500 are provided in a region wider than lower surfaces of the base chip 100 and the plurality of memory chips 200 is called a fan-out (FO) package structure. A package structure in which the external connection terminals 500 are provided in only the portion corresponding to the lower surfaces of the base chip 100 and the plurality of memory chips 200 is called a fan-in (FI) package structure.

Although a HBM package is mainly described above, a semiconductor package of some example embodiments is not limited to the HBM package. For example, the semiconductor package of some example embodiments may be applied to semiconductor packages, each, or one or more, having a structure in which a semiconductor chip is bonded to another semiconductor chip through HCB on a wafer. The semiconductor package of some example embodiments is not limited to stacking of semiconductor chips through HCB of pads, and may be applied to semiconductor packages, each, or one or more, having a structure in which semiconductor chips are stacked through separately provided bonding metals.

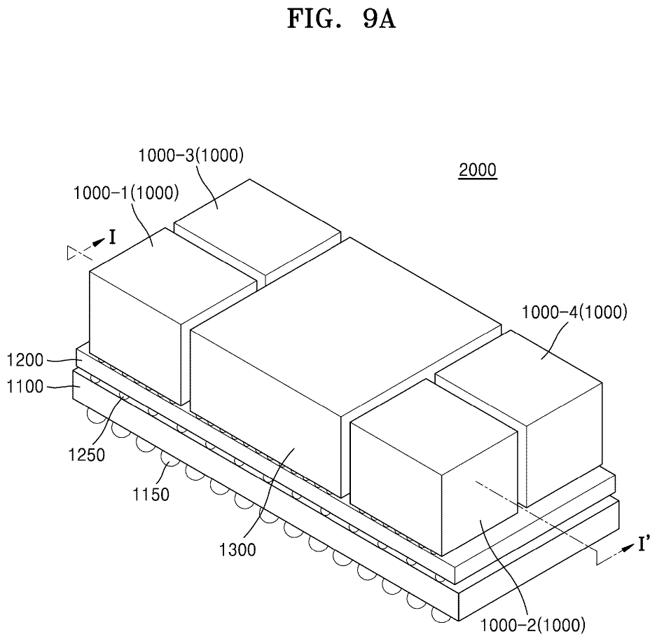

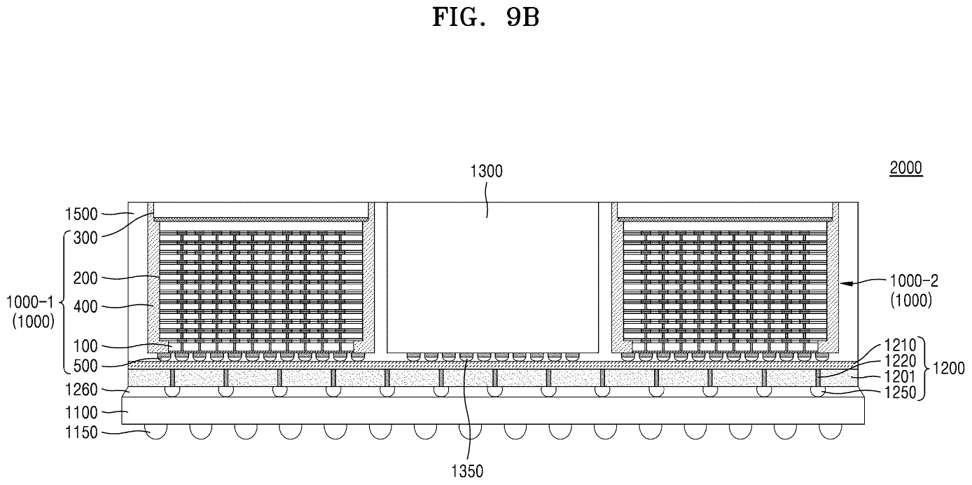

FIG. 9A and FIG. 9B are respectively a perspective view and a cross-sectional view of a system package 2000 according to some example embodiments. FIG. 9B may correspond to a cross-sectional view taken along line I-I′ of FIG. 9A. Descriptions are made with reference to FIG. 1A to FIG. 2 together, and the descriptions given above with reference to FIG. 1 to FIG. 8 are briefly made or omitted.

Referring to FIG. 9A and FIG. 9B, the system package 2000 of some example embodiments may include semiconductor packages 1000, a package substrate 1100, an interposer 1200, a semiconductor device 1300, and/or an external sealant 1500.

As illustrated in FIG. 9A, the semiconductor packages 1000 may include first, second, third, and/or fourth semiconductor packages 1000-1, 1000-2, 1000-3, and/or 1000-4. For example, the semiconductor packages 1000 may be provided on the interposer 1200 on two sides of the semiconductor device 1300. However, in the system package 2000 of some example embodiments, the number of semiconductor packages 1000 is not limited to four. For example, one to three semiconductor packages 1000 or five or more semiconductor packages 1000 may be arranged on the interposer 1200.

The semiconductor packages 1000 may each, or one or more, correspond to, for example, the semiconductor package 1000 of FIG. 1A or FIG. 1B. Accordingly, the semiconductor packages 1000 may each, or one or more, include a base chip 100, a plurality of memory chips 200, a top dummy chip 300, a sealant 400, and/or external connection terminals 500. A horizontal width of the base chip 100 may be less than horizontal widths of the plurality of memory chips 200.

In the system package 2000 of some example embodiments, the semiconductor packages 1000 may each, or one or more, be an HBM package. Accordingly, the base chip 100 of each, or one or more, of the semiconductor packages 1000 may be a buffer chip, and the plurality of memory chips 200 may each be a DRAM chip. However, the semiconductor package 1000 is not limited to the HBM package. Also, the semiconductor package 1000 is not limited to the semiconductor package 1000 of FIG. 1A and FIG. 1B. For example, instead of the semiconductor package 1000 of FIG. 1A and FIG. 1B, the semiconductor packages 1000A, 1000B, 1000C, 1000D, and/or 1000E of FIG. 4 to FIG. 8 may be applied to the system package 2000.

The package substrate 1100 is a support substrate, and the interposer 1200, the semiconductor packages 1000, and/or the semiconductor device 1300 may be stacked on the package substrate 1100. The package substrate 1100 may include wiring lines of at least one layer therein. When the wiring lines includes multiple layers, the wiring lines of different layers may be connected to each other through vertical vias. The package substrate 1100 may be formed based on, for example, a ceramic substrate, a printed circuit board (PCB), an organic substrate, an interposer substrate, and/or so on. First connection terminals 1150 may be provided on a lower surface of the package substrate 1100. The system package 2000 may be stacked onto an external system substrate and/or main board through the first connection terminals 1150.

The interposer 1200 may include an interposer substrate 1201, a wiring layer 1210, through-electrodes 1220, and/or second connection terminals 1250. The semiconductor packages 1000 and/or the semiconductor device 1300 may be mounted on the package substrate 1100 via the interposer 1200. The interposer 1200 may connect the semiconductor packages 1000 to the semiconductor device 1300. For example, the interposer 1200 may connect the semiconductor packages 1000 and/or the semiconductor device 1300 to the package substrate 1100.

The interposer substrate 1201 may include, for example, silicon (Si). Accordingly, the interposer 1200 may be a Si-interposer. The through-electrodes 1220 may extend by passing through the interposer substrate 1201. Because the interposer substrate 1201 includes silicon (Si), the through-electrodes 1220 may correspond to TSVs. The through-electrodes 1220 may extend to the wiring layer 1210 to be connected to the wiring lines of the wiring layer 1210. According to some example embodiments, the interposer 1200 may include only a wiring layer therein and may not include the through-electrodes 1220. The wiring layer 1210 may be on an upper surface and/or lower surface of the interposer substrate 1201. For example, a positional relationship between the wiring layer 1210 and the through-electrodes 1220 may be relative. Pads on an upper surface of the interposer 1200 may be respectively connected to the through-electrodes 1220 through the wiring layer 1210.

The second connection terminals 1250 may be provided on a lower surface of the interposer 1200 and respectively connected to the through-electrodes 1220. The interposer 1200 may be stacked on the package substrate 1100 through the second connection terminals 1250. The second connection terminals 1250 may be respectively connected to pads on an upper surface of the interposer 1200 through the wiring lines of the through-electrodes 1220 and/or the wiring layer 1210.

In the system package 2000 of some example embodiments, the interposer 1200 may be used for the purpose of converting an electrical signal between the semiconductor packages 1000 and the semiconductor device 1300, and/or transmitting the electric signal. Accordingly, the interposer 1200 may not include devices, such as active devices and/or passive devices. However, in some example embodiments, the interposer 1200 may include devices for controlling signal transmission. In addition, an underfill 1260 may be filled between the interposer 1200 and the package substrate 1100, and between the second connection terminals 1250. In some example embodiments, the underfill 1260 may be replaced with an adhesive layer and/or an adhesive film.

In some example embodiments, the system package 2000 may not include the interposer 1200. Accordingly, the semiconductor packages 1000 may be directly mounted on the package substrate 1100 through the external connection terminals 500. For example, the system package 2000 may further include a Si-bridge inside the package substrate 1100. The Si-bridge may connect the semiconductor packages 1000 to the semiconductor device 1300. In some example embodiments, the system package 2000 may further include the Si-bridge inside the interposer 1200 to connect the semiconductor packages 1000 to the semiconductor device 1300.

The semiconductor device 1300 may be stacked on a central portion of the interposer 1200 through third connection terminals 1350. The semiconductor device 1300 may have a chip structure and/or a package structure. In the system package 2000 of some example embodiments, the semiconductor device 1300 may have a chip structure. For example, the semiconductor device 1300 may include a logic chip. The semiconductor device 1300 may include a plurality of logic devices therein. The plurality of logic devices may include, for example, AND gates, NAND gates, OR gates, NOR gates, exclusive OR (XOR) gates, exclusive NOR (XNOR) gates, inverters (INVs), adders (ADDs), delays (DLYs), filters (FILs), multiplexers (MXT/MXIT), OR/AND/INVERTER (OAI), AND/OR (AO) gates, AND/OR/INVERTER (AOI), D flip-flops, reset flip-flops, master-slave flip-flops, latches, counters, and/or buffer devices. The plurality of logic devices may perform various type of signal processing, such as analog signal processing, analog-digital (A/D) conversion, and control. The semiconductor device 1300 may be referred to as a central processing unit (CPU) chip, a system on glass (SOG) chip, a micro-processor unit (MPU) chip, a graphics processing unit (GPU) chip, a neural processing unit (NPU) chip, an application processor (AP) chip, a control chip, and/or so on depending on functions.

In the system package 2000 of some example embodiments, the semiconductor device 1300 may have a chip structure but may have a system on chip (SoC) structure or a chiplet structure. The SoC structure may be a structure in which multiple systems are integrated into one chip. Accordingly, the semiconductor device 1300 having the SoC structure may perform a computational function, data storage, analog and digital signal conversion, and so on in one chip. In addition, the chiplet structure may include a structure in which a logic chip is divided into separate chips by function and the separate chips is connected to each other. The semiconductor device 1300 having the chiplet structure may overcome a performance limitation of a single chip.

The external sealant 1500 may cover and/or seal the semiconductor device 1300 and/or the semiconductor packages 1000 on the interposer 1200. As illustrated in FIG. 9B, the external sealant 1500 may not cover upper surfaces of the semiconductor device 1300 and/or the semiconductor packages 1000. However, in some example embodiments, the external sealant 1500 may cover either an upper surface of the semiconductor device 1300 or upper surfaces of the semiconductor packages 1000. Although not illustrated in FIG. 9A and FIG. 9B, the system package 2000 of some example embodiments may also further include a second external sealant that covers and/or seals the interposer 1200 and/or the external sealant 1500 on the package substrate 1100.

For example, a structure of the system package 2000 of some example embodiments may be called a 2.5-dimensional (2.5D) package structure, and the 2.5D package structure may be a relative concept to a three-dimensional (3D) package structure in which all, or one or more, semiconductor chips are stacked together and there is no interposer. Both the 2.5D package structure and the 3D package structure may be included in a system in package (SIP) structure. In addition, the system package 2000 of some example embodiments is also a semiconductor package, and may be named as a system package to be distinguished from the semiconductor package 1000 which is a component in terms of terminology.

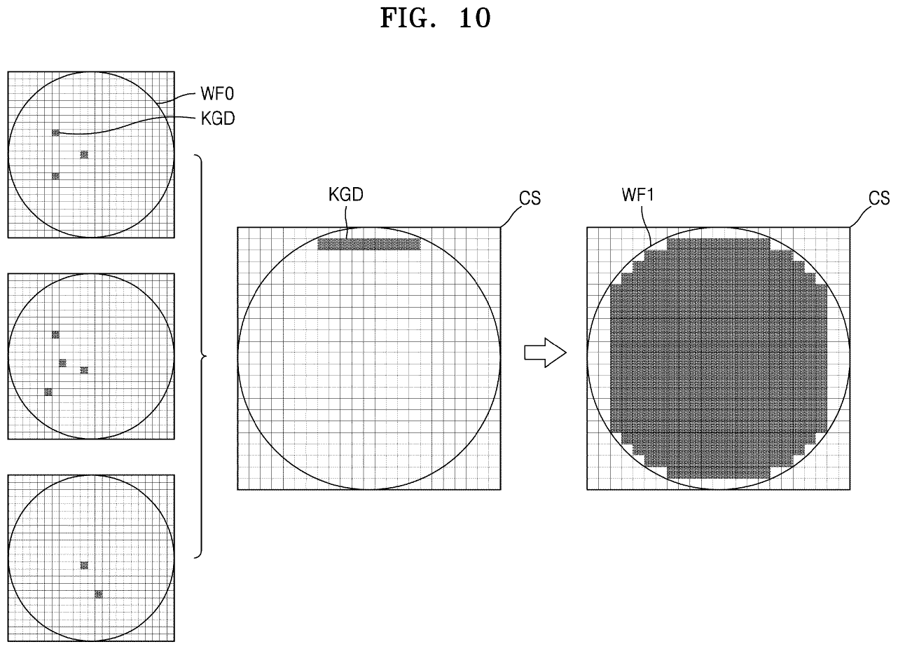

FIG. 10 to FIG. 13 are plan views simply illustrating a method of manufacturing a semiconductor package, according to some example embodiments. FIG. 10 to FIG. 13 are views illustrating a process of packaging a semiconductor on a wafer.

Referring to FIG. 10, a re-construction process may be performed to select known good dies KGD from among base chips manufactured on a wafer WF0 and attach the known good dies KGD on a carrier substrate CS. For example, the carrier substrate SC may include a film material. A wafer WF1 may be manufactured to include only good dies through the re-construction process. Because the yield of a semiconductor package manufactured by stacking memory chips on a base chip is affected by the yield of the base chip, the yield of the semiconductor package may be improved by removing defective base chips through the re-construction process.

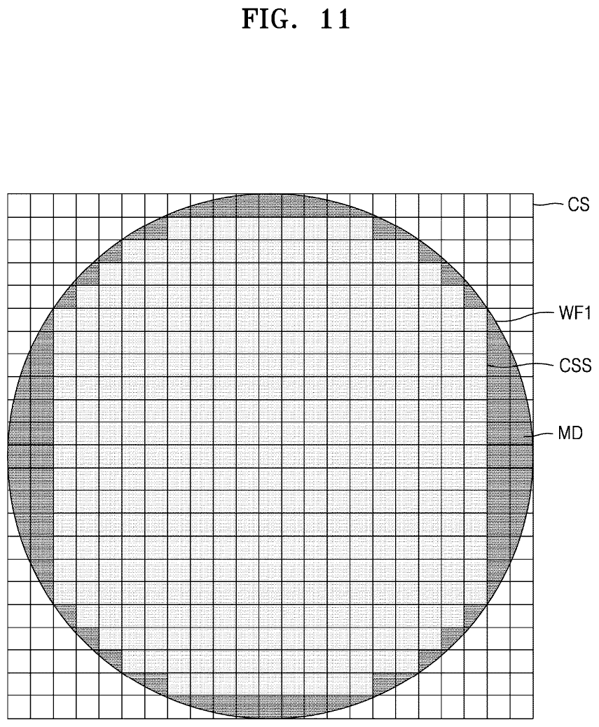

Referring to FIG. 11, memory chips may be respectively stacked on base chips of the wafer WF1 of FIG. 10 through HCB. A top dummy chip may be stacked on an upper portion of the memory chips through an adhesive layer. A sealant MD may be formed to seal a chip stack structure CSS including a base chip, memory chips, and/or a top dummy chip.

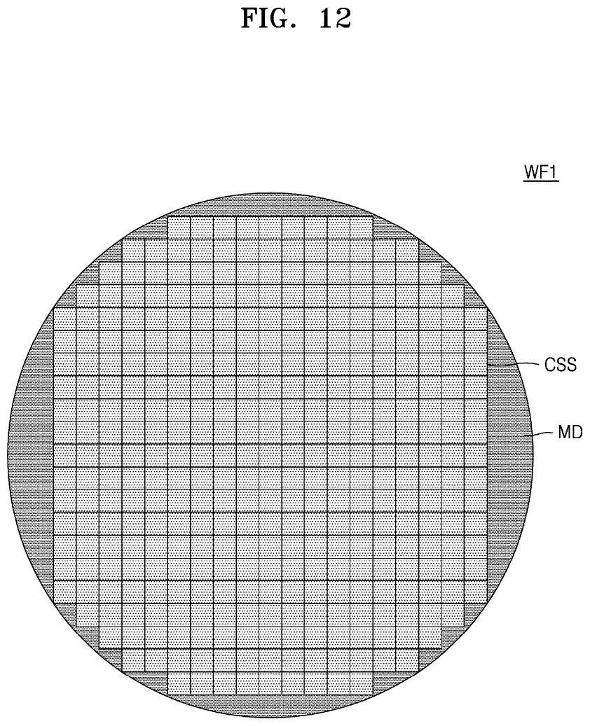

Referring to FIG. 12, the wafer WF1, which is a result of FIG. 11 and on which the chip stack structure CSS and/or the sealant MD are formed, may be separated (de-bonded) from the carrier substrate CS and be turned over to be prepared.

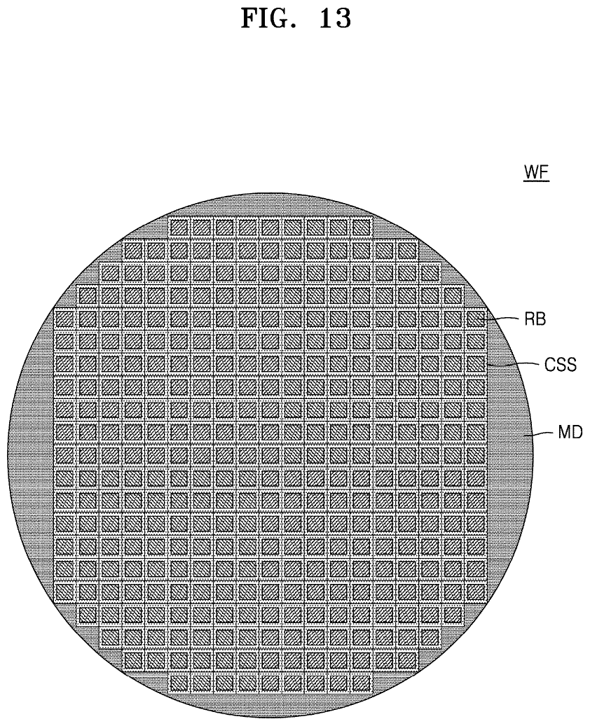

Referring to FIG. 13, a bumping process may be performed to form a redistribution layer (RDL) RB on each chip stack structure CSS in the result of FIG. 11 and to form an external connection terminal. Thereafter, a sawing process may be performed to separate respective semiconductor packages.

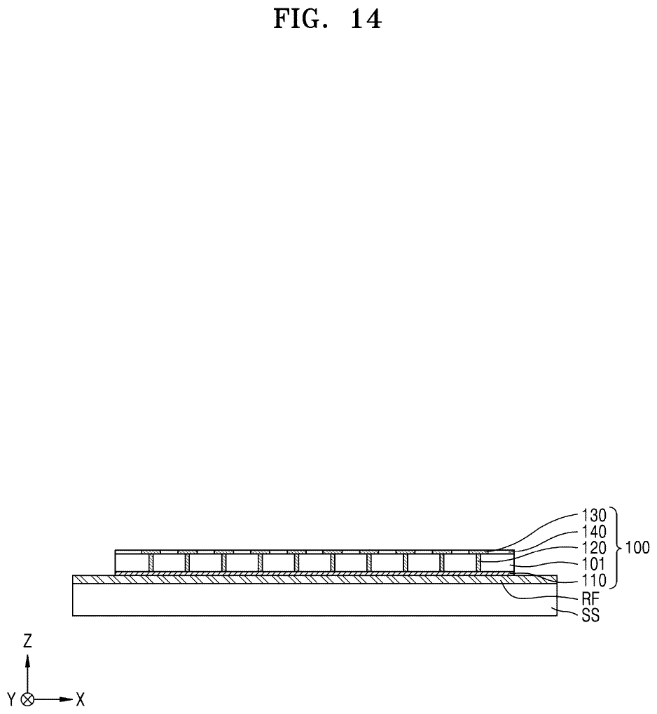

FIGS. 14 to 20 are cross-sectional views simply illustrating a method of manufacturing the semiconductor package 1000, according to some example embodiments. FIGS. 14 to 20 may be cross-sectional views illustrating in detail a process of forming a semiconductor package through, for example, the processes of FIG. 11 to FIG. 13.

Referring to FIG. 14, a base chip 100 may be attached to a support substrate SS. The base chip 100 may be attached to the support substrate SS through a release film RF. The release film RF may be first attached to an upper surface of the support substrate SS, and then the base chip 100 may be attached onto the release film RF. Here, the support substrate SS may correspond to the carrier substrate CS of FIG. 11. The base chip 100 may be attached onto the release film RF such that an active layer 110 faces the support substrate SS.

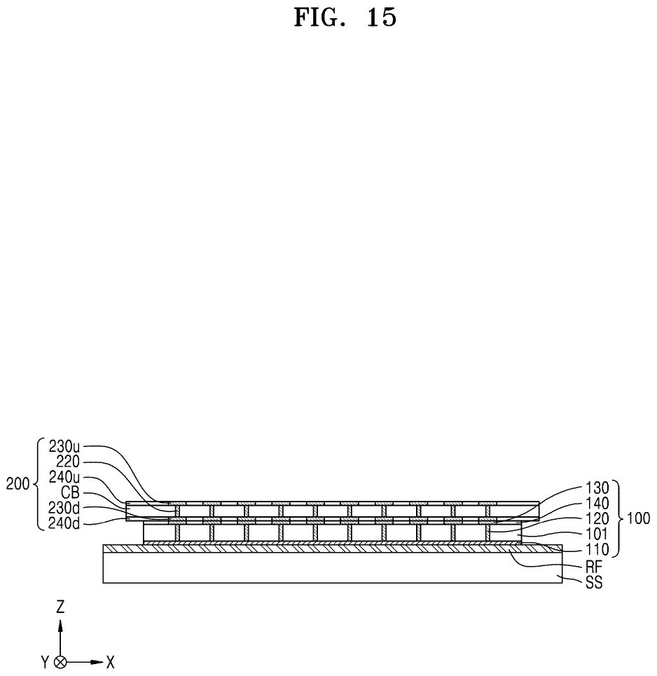

Referring to FIG. 15, a first memory chip 200-1 may be stacked on the base chip 100. The first memory chip 200-1 may be bonded to the base chip 100 through HCB. Upper pads 130 of the base chip 100 may be bonded to lower pads 230d of the first memory chip 200-1, and/or a protective layer 140 of the base chip 100 may be bonded to a lower protective layer 240d of the first memory chip 200-1, and accordingly, HCB may be formed between the base chip 100 and the first memory chip 200-1.

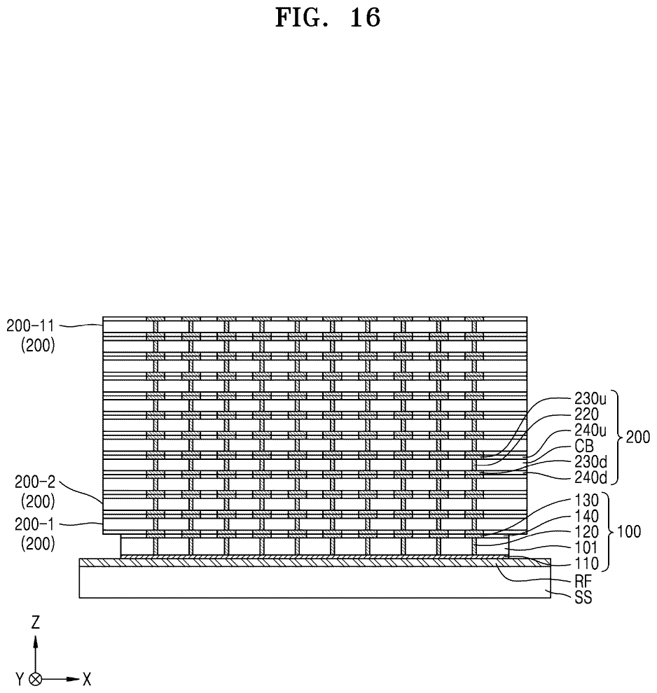

Referring to FIG. 16, second to 11^{th} memory chips 200-2 to 200-11 may be sequentially stacked on the first memory chip 200-1. Two adjacent memory chips 200 may be bonded to each other through HCB. The upper pads 230u and the upper protective layer 240u on an upper surface of the memory chip 200 at a lower portion may be respectively bonded to the lower pads 230d and the lower protective layer 240d on a lower surface of the memory chip 200 at an upper portion to form HCB.

Horizontal widths of the memory chips 200 may be greater than a horizontal width of the base chip 100. The memory chips 200 are stacked such that edges of the memory chips 200 are located on an outer portion of the base chip 100. For example, a corner and/or edge of the first memory chip 200-1, in which separation may easily occur, may not be in contact with the base chip 100.

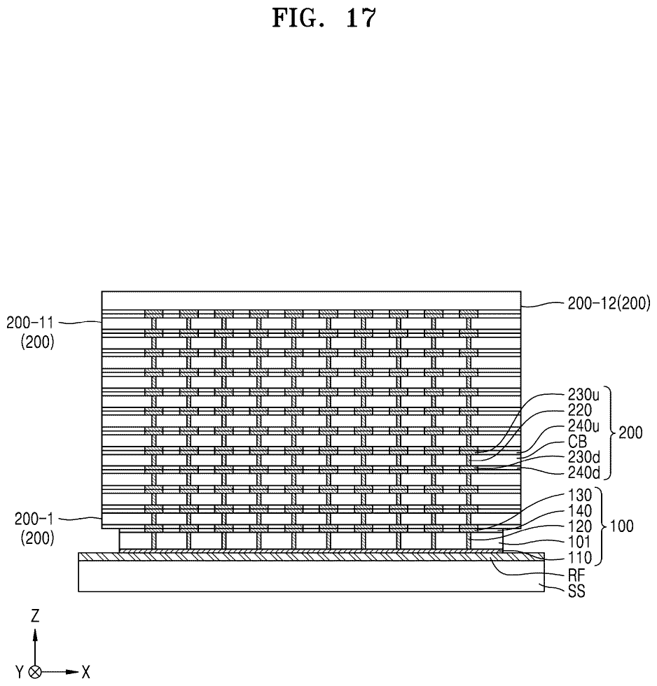

Referring to FIG. 17, a 12^{th} memory chip 200-12 may be stacked on the 11^{th} memory chip 200-11. The 12^{th} memory chip 200-12 may be bonded to the 11^{th} memory chip 200-11 through HCB. The 12^{th} memory chip 200-12 may not include through-electrodes as a memory chip located at an uppermost portion. The 12^{th} memory chip 200-12 may be thicker than the other memory chips 200.

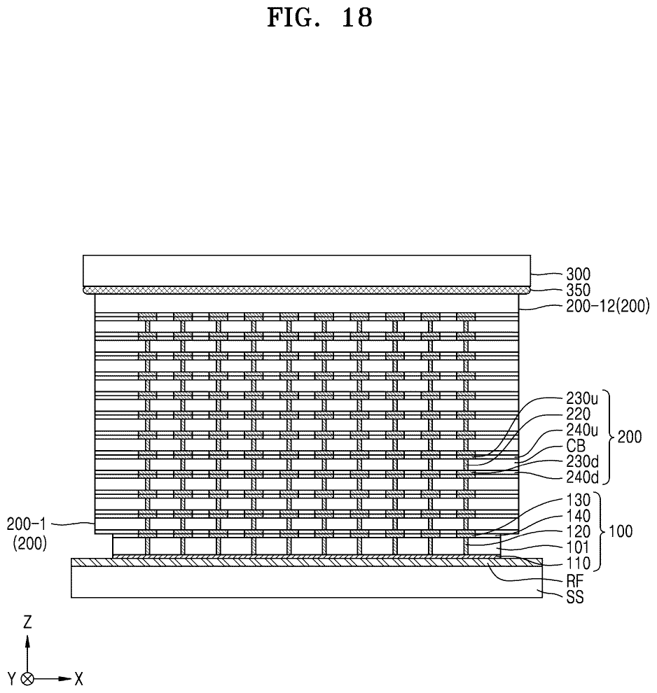

Referring to FIG. 18, a top dummy chip 300 may be stacked on an upper portion of the memory chips 200. The top dummy chip 300 may be stacked on the 12^{th} memory chip 200-12, and an adhesive layer 350 may be provided between the top dummy chip 300 and the 12^{th} memory chip 200-12. In some example embodiments, the adhesive layer 350 may include an NCF or a DAF. For example, a horizontal width of the top dummy chip 300 may be greater than or equal to horizontal widths of the memory chips 200, and accordingly, the adhesive layer 350 may not extend to a side surface of the top dummy chip 300.

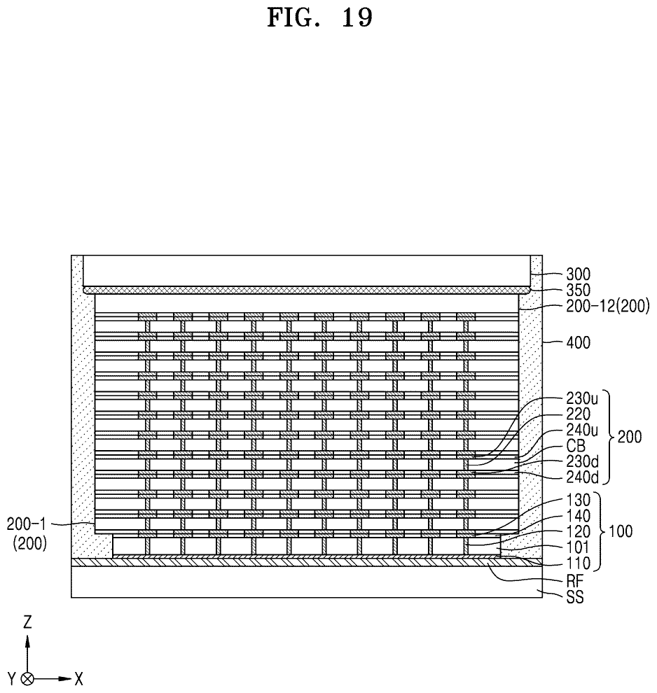

Referring to FIG. 19, a sealant 400 may be formed on the support substrate SS. The sealant 400 may seal a side surface of the base chip 100, side surfaces of the memory chips 200, a portion of a lower surface of the first memory chip 200-1 which is not in contact with the base chip 100, and/or a side surface of the top dummy chip 300. The sealant 400 may not cover an upper surface of the top dummy chip 300. Accordingly, the upper surface of the top dummy chip 300 may be exposed from the sealant 400. In order to reduce, or prevent, the sealant 400 from covering the upper surface of the top dummy chip 300, a process of grinding a part of an upper surface of the sealant 400 and a part of an upper part of the top dummy chip 300 may be performed.

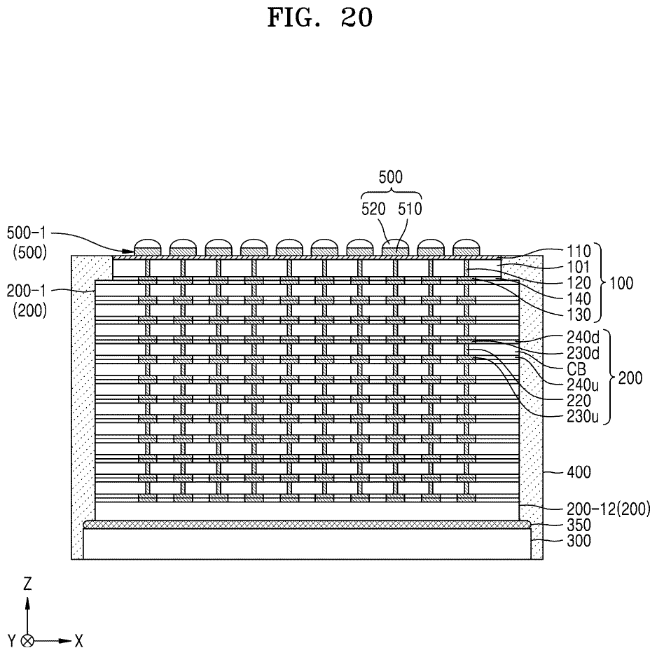

Referring to FIG. 20, the support substrate SS to which the release film RF is attached may be separated from a result of FIG. 19, and the result may be turned over to be prepared. Thereafter, external connection terminals 500 may be formed on the base chip 100. The external connection terminals 500 may be respectively connected to wires of a multi-wiring layer of the active layer 110. The external connection terminals 500 may each, or one or more, include a pillar 510 and a bump 520. In some example embodiments, some of the external connection terminals 500 may be in contact with the sealant 400. For example, a first external connection terminal 500-1 at an outermost end among the external connection terminals 500 may be provided across the base chip 100 and the sealant 400. A part of the first external connection terminal 500-1 may vertically overlap the base chip 100, and the other portions of the first external connection terminal 500-1 may vertically overlap the sealant 400.

Depending on processes, a redistribution layer (the redistribution layer 600 of FIG. 6) may be formed on the base chip 100 before the external connection terminals 500 are formed. In this case, the external connection terminals 500 may be formed on the redistribution layer 600.

According to some example embodiments of the inventive concepts, a method for manufacturing a semiconductor package includes, attaching a base chip to a support substrate, the base chip having a first horizontal width, bonding a plurality of memory chips to the base chip, the plurality of memory chips having a second horizontal width greater than the first horizontal width, and forming a sealant on the support substrate, the sealant sealing a side surface of the base chip, side surfaces of the plurality of memory chips, and a portion of a lower surface of a first memory chip that is lowermost among the plurality of memory chips, the portion of the lower surface of the first memory chip not contacting the base chip.

According to some example embodiments, the bonding the plurality of memory chips includes bonding the plurality of memory chips through hybrid copper bonding (HCB).

According to some example embodiments, the bonding the plurality of memory chips includes bonding the first memory chip to the base chip through HCB, and bonding the plurality of memory chips to each other through HCB.

According to some example embodiments, the method may further include bonding a top dummy chip to the plurality of memory chips using an adhesive layer, the top dummy chip having a third horizontal width greater than or equal to the second horizontal width.

According to some example embodiments, the forming the sealant includes forming the sealant sealing a side surface of the top dummy chip, not covering a top surface of the top dummy chip, and not covering a lower surface of the base chip.

According to some example embodiments, the method may further include, grinding a part of an upper surface of the sealant and a part of on an upper surface of the top dummy chip.

According to some example embodiments, a thickness of the top dummy chip may be greater than a thickness of the base chip.

According to some example embodiments, a thickness of the base chip may be greater than or equal to a thickness of each memory chip of the plurality of memory chips.

According to some example embodiments, the bonding the plurality of memory chips to the base chip includes bonding the plurality of memory chips to the base chip with no connection terminals between the base chip and between adjacent memory chips.

Although the inventive concepts are described above with reference to some example embodiments illustrated in the drawings, the example embodiments are merely examples, and those skilled in the art will understand that various modifications and equivalent to some example embodiments may be derived therefrom. Therefore, the true technical protection scope of the inventive concepts should be determined by the inventive concepts of the appended patent claims.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a base chip having a first horizontal width;
a plurality of memory chips on the base chip, each memory chip of the plurality of memory chips having a second horizontal width; and
a sealant sealing a side surface of the base chip, side surfaces of the plurality of memory chips, and a portion of a lower surface of a first memory chip that is lowermost among the plurality of memory chips, the portion of the lower surface of the first memory chip not contacting the base chip,
wherein the first horizontal width is less than the second horizontal width.

2. The semiconductor package of claim 1, further comprising:
a top dummy chip stacked on an upper portion of the plurality of memory chips through an adhesive layer,
wherein the top dummy chip has a third horizontal width greater than or equal to the second horizontal width.

3. The semiconductor package of claim 2, wherein the sealant further seals a side surface of the top dummy chip and does not cover a lower surface of the base chip and an upper surface of the top dummy chip.

4. The semiconductor package of claim 1, wherein a thickness of the base chip is greater than or equal to a thickness of each of the plurality of memory chips.

5. The semiconductor package of claim 2, wherein a thickness of the top dummy chip is greater than a thickness of the base chip.

6. The semiconductor package of claim 1, wherein a ratio of a thickness of the base chip to half of a difference between the first horizontal width and the second horizontal width is 20 or less.

7. The semiconductor package of claim 1, wherein
the base chip includes a logic chip, and
each of the plurality of memory chips includes a dynamic random-access memory (DRAM) chip.

8. The semiconductor package of claim 1, wherein no connection terminals are between the first memory chip and the base chip and between adjacent memory chips.

9. The semiconductor package of claim 1, wherein
the first memory chip and the base chip are bonded to each other through hybrid copper bonding (HCB), and
the plurality of memory chips are bonded to each other through HCB.

10. A semiconductor package comprising:
a base chip having a first horizontal width;
a plurality of memory chips stacked on the base chip through hybrid copper bonding (HCB) and having a second horizontal width;
a redistribution layer on a lower surface of the base chip; and
a sealant sealing a side surface of the base chip, side surfaces of the plurality of memory chips, and a portion of a lower surface of a first memory chip that is lowermost among the plurality of memory chips, the portion of the lower surface of the first memory chip not contacting the base chip,
wherein the first horizontal width is less than the second horizontal width.

11. The semiconductor package of claim 10, wherein a thickness of the base chip is greater than or equal to a thickness of each of the plurality of memory chips.

12. The semiconductor package of claim 10, further comprising:
a top dummy chip stacked on an upper portion of the plurality of memory chips through an adhesive layer,
wherein the top dummy chip has a third horizontal width greater than or equal to the second horizontal width.

13. The semiconductor package of claim 12, wherein the sealant further seals a side surface of the top dummy chip and does not cover a lower surface of the base chip and an upper surface of the top dummy chip.

14. The semiconductor package of claim 10, further comprising:
external connection terminals on a lower surface of the base chip,
wherein part of a first external connection terminal that is outermost among the external connection terminals overlaps the base chip, and the remaining part of the first external connection terminal overlaps the sealant.

15. The semiconductor package of claim 10, further comprising:
external connection terminals on a lower surface of the redistribution layer,
wherein a first external connection terminal that is outermost among the external connection terminals does not overlap the base chip.

16. A semiconductor package comprising:
a package substrate;
a first semiconductor device on the package substrate; and
at least one second semiconductor device adjacent to the first semiconductor device on the package substrate,
wherein the second semiconductor device has a package structure including
a base chip having a first horizontal width,
a plurality of memory chips on the base chip, each memory chip of the plurality of memory chips having a second horizontal width, and
a sealant sealing a side surface of the base chip, side surfaces of the plurality of memory chips, and a portion of a lower surface of a first memory chip that is lowermost among the plurality of memory chips,
wherein the portion of the lower surface of the first memory chip is not in contact with the base chip, and
wherein the first horizontal width is less than the second horizontal width.

17. The semiconductor package of claim 16, further comprising:
a top dummy chip stacked on an upper portion of the plurality of memory chips through an adhesive layer,
wherein the top dummy chip has a third horizontal width greater than or equal to the second horizontal width.

18. The semiconductor package of claim 16, wherein a thickness of the base chip is greater than or equal to a thickness of each of the plurality of memory chips.

19. The semiconductor package of claim 16, wherein
the first semiconductor device includes a logic chip, and
the at least one second semiconductor device includes a high bandwidth memory (HBM) package.

20. The semiconductor package of claim 16, further comprising
an interposer on the package substrate,
wherein the first semiconductor device and the at least one second semiconductor device are electrically connected to the package substrate through the interposer.
